(19) United States
(12) Patent Application Publication
(10) Pub. No.: US 2006/0239321 A1
(43) Pub. Date: Oct. 26, 2006

(54) Semiconductor laser device

(75) Inventors: Masahiro Kume, Shiga (JP); Toshitaka Shimamoto, Osaka (JP); Isao Kidoguchi, Hyogo (JP); Tomoaki Uno, Hyogo (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.**

(21) Appl. No.: 11/327,405

(22) Filed: Jan. 9, 2006

(30) Foreign Application Priority Data
Apr. 26, 2005 (JP) 2005-128740

(51) Int. Cl. H01S 5/00

(52) U.S. Cl. 372/50.121; 372/50.1; 372/50.12; 372/50.122

(57) ABSTRACT

A semiconductor laser device includes a first semiconductor laser element for emitting a first laser light having a first oscillation wavelength of λ₁ and a second semiconductor laser element for emitting a second laser light having a second oscillation wavelength of λ₂ (wherein λ₂≧λ₁), which are formed on a single substrate. A first dielectric film which has a refractive index of n₁ with respect to a wavelength λ between the first oscillation wavelength λ₁ and the second oscillation wavelength λ₂ and has a film thickness of approximately λ/(8n₁) is formed at light emitting facets in the first semiconductor laser element and the second semiconductor laser element, from which the laser lights are emitted, and a second dielectric film having a refractive index of n₂ and a film thickness of λ/(8n₂) are formed on the first dielectric film.

### CROSS REFERENCE TO RELATED APPLICATIONS

This Non-provisional application claims priority under 35 U.S.C. § 119(a) on Patent Application No. 2005-128740 filed in Japan on Apr. 26, 2005, the entire contents of which are hereby incorporated by reference.

### BACKGROUND ART

The present invention relates to a single-wavelength or dual-wavelength semiconductor laser device used as a light source for an optical disk.

Semiconductor laser devices are widely employed in various fields such as electronics, optoelectronics, and the like, and are indispensable to optical devices. Especially, optical disks such as CDs (compact disks), DVDs (digital versatile disks), and the like are utilized increasingly as large-capacity recording media. The recording media used in the DVDs are smaller in pit length and track interval than the recording media used in the CDs. Accordingly, the wavelength of the laser light used in the DVDs is shorter than that used in the CDs. Specifically, the oscillation wavelength of the laser light for the CDs is at a 780 nm band while the oscillation wavelength of the laser light used for the DVDs is at a 650 nm band.

In order to allow a single optical disk device to detect information of both the CDs and the DVDs, two laser light sources, that is, a 780 nm band laser light source (an infrared semiconductor laser element) and a 650 nm band laser light source (a red semiconductor laser element) are necessary. Recently, a semiconductor laser device provided with a single semiconductor chip capable of generating two kinds of laser lights having different wavelengths has been developed with the aim of reduction in size and weight of an optical pickup section composing an optical disk device, and are becoming widespread.

FIG. 10A and FIG. 10B are a perspective view and a sectional view of a conventional dual-wavelength semiconductor laser device 100 (see, for example, Japanese Patent Application Laid Open Publication No. 2002-223030A, hereinafter referred to as Reference 1), respectively. As shown in FIG. 10A and FIG. 10B, the semiconductor laser device 100 includes two laser elements of a red semiconductor laser element 10 for emitting a laser light 15 having a wavelength band of 650 nm and an infrared semiconductor laser element 20 for emitting a laser light 25 having a wavelength band of 780 nm.

In the semiconductor laser device 100, an isolation trench 90 is formed for electrically isolating the red semiconductor laser element 10 and the infrared semiconductor laser element 20. Two p-side electrodes 30 are formed on the upper face of the semiconductor laser device 100 so as to be separated by the isolation trench 90 while an n-side electrode 40 are formed on the whole bottom face thereof, so that the semiconductor laser elements 20, 30 are operated independently by individually applying bias voltage to the two p-side electrodes 30 and the one n-side electrode 40.

The semiconductor laser device 100 includes a front facet 50 for taking out the respective laser lights 15, 25 and a rear face for allowing lights to reflect at the inside of cavities for light confinement. A multilayered coating film 80 is layered on the rear facet 60. On the other hand, facet coating films 70, 72 having a reflectance lower than that of the rear facet 60 are formed on the front facet 50 for increasing efficiency of taking out the laser lights.

Herein, Reference 1 discloses a technique of forming the facet coating films 70, 72 which set the reflectance of the front facet 50 in the region of the red semiconductor laser element 10 used for DVD replay (DVD-ROM) to be approximately 20% and set the reflectance of the front facet 50 in the region of the infrared semiconductor laser element 20 used for CD replay (CD-ROM) to be approximately 5% or less. The facet coating films 70, 72 are made of two kinds of materials (Al₂O₃ and SiO₂, for example), and each film thickness thereof is determined so as to obtain desired reflectance of the front facet 50.

Further, Japanese Patent Application Laid Open Publication No. 2001-320131A (hereinafter referred to as Reference 2) discloses a dual-wavelength semiconductor laser device in which the reflectance of the front facet is controlled to be in the range between 24% and 32% and the reflectance of the front face in the region of the red semiconductor laser element used for DVD replay (DVD-ROM) is set lower than the reflectance of the front facet in the region of the infrared semiconductor laser element used for CD replay (CD-ROM). Specifically, the film thickness is set so that the reflectance of the front facet in the region of the red semiconductor laser element is 24% and the reflectance of the front facet in the region of the infrared semiconductor laser element is 32%, and an aluminum oxide (Al₂O₃) is formed on the front facet by one-time deposition step by vacuum evaporation. The film thickness is set to be λ₃/(2n₃) where the wavelength of the infrared semiconductor laser element is λ₃ and the refractive index of Al₂O₃ is n₃ (approximately 1.66). In this methodology, Reference 2 tries to attain a device in which a kink level and an optical damage (catastrophic optical damage: COD) level are substantially equal between the red semiconductor laser element and the infrared semiconductor laser element. Wherein, the kink level means a light output value at which nonlinearity occurs in a current-light output characteristic, and the COD level means a light output value at which crystallinity of the front facet in the active layer is degraded due to temperature rise in the front facet coating film.

On the other hand, as one of effective approaches to high power output operation, there is proposed a method in which the reflectances of the front facet and the rear facet, which form a cavity of the semiconductor laser device, are differentiated from each other so that the front and rear facets are made asymmetric in reflectance (see, for example, “Semiconductor Laser,” edited by Kenichi Iga, published by Ohmsha, Ltd., First publication, First print, page 238, hereinafter referred to as Reference 3). This approach is a general scheme in the filed of semiconductor laser devices used for writing in optical disk devices. Specifically, the semiconductor laser device is made asymmetric between the front facet and the rear facet by coating the facets forming the cavity with a multilayered film made of dielectrics, wherein the reflectance of the front facet is set low to be approximately 10% while the reflectance of the rear facet is set high to be approximately 90%. The reflectance of the multilayered film made of different dielectrics can be adjusted according to the refractive indices, the film thickness, and the number of layers of the dielectrics.

### SUMMARY OF THE INVENTION

However, the multi-wavelength semiconductor laser devices (arrays) disclosed in References 1 and 2 offer methods for forming the facet coating films suitable for the red semiconductor laser element and the infrared semiconductor laser element for a limited purpose of exclusive replay of DVD-ROM and CD-ROM and are effective only in the case where the semiconductor laser devices are operated at lower output power of, for example, approximately 5 mW as a rated output.

Under the circumstances, it is difficult for the multi-wavelength semiconductor laser devices disclosed in References 1 and 2 to attain high power output operation necessary for writing into various recording media such as DVD-RAM, DVD-R, CD-R, and the like. Also, Reference 3 merely refers to a general technique for attaining high power output operation in a semiconductor laser device and fails to present a suitable condition for a multi-wavelength semiconductor laser device in which a plurality of semiconductor laser elements for outputting laser lights having different oscillation wavelengths are formed on a single substrate.

The present invention has its objective of enabling easy formation of a facet coating film that can attain high power output characteristic and high reliability in a semiconductor laser device in which a plurality of semiconductor laser elements having different wavelengths are formed monolithically.

To attain the above objective, a dual-wavelength semiconductor laser device of the present invention is so constituted that the film thicknesses of a first dielectric film having a refractive index of n₁ and a second dielectric film having a refractive index of n₂, which compose a facet coating film of front facets (light emitting facets) of the semiconductor laser elements, are set to be approximately λ/(8n₁) and λ/(8n₂), respectively, where λ is approximately an intermediate value between the oscillation wavelengths of the semiconductor laser elements.

Specifically, a first semiconductor laser device of the present invention includes: a first semiconductor laser element formed on one substrate for emitting a first laser light having a first oscillation wavelength of λ₁; and a second semiconductor laser element formed on the substrate for emitting a second laser light having a second oscillation wavelength of λ₂ (wherein λ₂≧λ₁), wherein a first dielectric film which has a refractive index of n₁ with respect to a wavelength λ between the first oscillation wavelength λ₁ and the second oscillation wavelength λ₂ and has a film thickness of approximately λ/(8n₁) is formed at light emitting facets in the first semiconductor laser element and the second semiconductor laser element, from which the laser lights are emitted, and a second dielectric film which has a refractive index of n₂ and has a film thickness of approximately λ/(8n₂) is formed on the first dielectric film.

In the first semiconductor laser element, the first dielectric film of which refractive index is n₁ and of which film thickness is approximately λ/(8n₁) with respect to the wavelength λ between the first oscillation wavelength λ₁ and the second oscillation wavelength λ₂ are formed at the light emitting facets for emitting the respective laser lights of the first semiconductor laser element and the second semiconductor laser element, and the second dielectric film of which refractive index is n₂ and of which film thickness is approximately λ/(8n₂) is formed on the first dielectric film. The facet coating film formed of the first dielectric film and the second dielectric film attains easy provision of the reflectance suitable for high power output operation for the light emitting facets. As a result, the kink level rises to increase reliability in high power output operation, thereby improving manufacturing yield.

The first semiconductor laser device is applicable to a single-wavelength semiconductor laser device in which the first oscillation wavelength λ₁ and the second oscillation wavelength λ₂ are equal to the wavelength λ.

In the first semiconductor laser device, a reflectance of the light emitting facets is preferably in a range beaten 1% and 7%, both inclusive.

A second semiconductor laser device of the present invention includes: a first semiconductor laser element formed on one substrate for emitting a first laser light having a first oscillation wavelength of λ₁; and a second semiconductor laser element formed on the substrate for emitting a second laser light having a second oscillation wavelength of λ₂ (wherein λ₂≧λ₁), wherein a first dielectric film which has a refractive index of n₁ with respect to a wavelength λ between the first oscillation wavelength λ₁ and the second oscillation wavelength λ₂ and has a film thickness of approximately λ/(8n₁) is formed at reflection facets located opposite light emitting facets in the first semiconductor laser element and the second semiconductor laser element, from which the laser lights are emitted, a second dielectric film which has a refractive index of n₂ and has a film thickness of approximately λ/(8n₂) is formed on the first dielectric film, a third dielectric film having a refractive index of n₃ (wherein n₃>n₁ and n₂) and has a film thickness of approximately λ/(4n₃) is formed on the second dielectric film, and a plurality of pairs of dielectric films are formed on the third dielectric film, each of the paired dielectric films being composed of a fourth dielectric film having a refractive index of n₄ and a film thickness of λ/(4n₄) and a fifth dielectric film having a refractive index of n₅ and a film thickness of λ/(4n₅).

In the second semiconductor laser device, the first dielectric film and the second dielectric film of the present invention are formed at the reflection facets located opposite the light emitting facets for emitting the respective laser lights of the first semiconductor laser element and the second semiconductor laser element, and the third dielectric film having a refractive index higher than that of the first and second dielectric films and the fourth dielectric film and the fifth dielectric film which are different in refractive index from each other are formed on the second dielectric film, thereby causing reflection of the respective laser lights within the respective cavities for confinement.

The second semiconductor laser device is applicable to a single-wavelength semiconductor laser device in which the first oscillation wavelength λ₁ and the second oscillation wavelength λ₂ are equal to the wavelength λ.

In the second semiconductor laser device, a reflectance of the reflection facets is preferably 70% or more.

In the first or second semiconductor laser device, it is preferable that the refractive index n₁ is in a range 1.6≦n₁≦2.3 and the refractive index n₂ is in a range 1.4≦n₂<1.6.

In the first or second semiconductor laser device, it is preferable that the first dielectric film is made of Al₂O₃, Ta₂O₅, Nb₂O₅, or ZrO₂ while the second dielectric film is made of SiO₂.

In the first or second semiconductor laser device, it is preferable that the first semiconductor laser element has an active layer made of AlGaInP-based semiconductor while the second semiconductor laser element has an active layer made of AlGaAs-based semiconductor.

Further, the semiconductor laser deice of the present invention may be a single-wavelength semiconductor laser device in which the active layer is made of AlGaInP-based semiconductor or AlGaAs-based semiconductor.

### BRIEF DESCRIPTION OF THE DRAWINGS

FIG. 1 is a schematic perspective view showing a dual-wavelength semiconductor laser device according to one embodiment of the present invention.

FIG. 2 is a sectional view in the direction interesting at a right angle with the direction in which a ridge stripe portion extends in the dual-wavelength semiconductor laser device according to the embodiment of the present invention.

FIG. 3 is a sectional view showing the ridge stripe portion in the direction parallel to a cavity of a red semiconductor laser element of the dual-wavelength semiconductor laser device according to the embodiment of the present invention.

FIG. 4 is a sectional view showing a ridge strip portion in the direction parallel to a cavity of an infrared semiconductor laser element of the dual-wavelength semiconductor laser device according to the embodiment of the present invention.

FIG. 5 is a graph indicating dependencies of characteristic temperature T₀ and kink level on reflectance of a front facet in the red semiconductor laser element according to the embodiment of the present invention.

FIG. 6A and FIG. 6B indicate film thickness dependencies of the reflectance of a facet coating film formed of an Al₂O₃ film and an SiO₂ film which is provided at the front facets of the dual-wavelength semiconductor laser device according to the embodiment of the present invention, wherein FIG. 6A is a graph indicating the reflectance to a light of which wavelength is 660 nm and FIG. 6B is a graph indicating the reflectance to a light of which wavelength is 780 nm.

FIG. 7A and FIG. 7B indicate film thickness dependencies of the reflectance of a facet coating film formed of an Ta₂O₅ film and an SiO₂ film which is provided at the front facets of the dual-wavelength semiconductor laser device according to the embodiment of the present invention, wherein FIG. 7A is a graph indicating the reflectance to a light of which wavelength is 660 nm and FIG. 7B is a graph indicating the reflectance to a light of which wavelength is 780 nm.

FIG. 8A and FIG. 8B indicate film thickness dependencies of the reflectance of a facet coating film formed of an Nb₂O₅ film and an SiO₂ film which is provided at the front facets of the dual-wavelength semiconductor laser device according to the embodiment of the present invention, wherein FIG. 8A is a graph indicating the reflectance to a light of which wavelength is 660 nm and FIG. 8B is a graph indicating the reflectance to a light of which wavelength is 780 nm.

FIG. 9 is a graph indicating isoreflectance contours to a light of which wavelength is 660 nm and a light of which wavelength is 780 nm with respect to the film thicknesses of the Al₂O₃ film and the SiO₂ film which form the facet coating film provided at the front facets of the dual-wavelength semiconductor laser device according to the embodiment of the present invention.

FIG. 10A and FIG. 10B shows a conventional dual-wavelength semiconductor laser device, wherein FIG. 10A is a perspective view and FIG. 10B is a sectional view in the direction parallel to the substrate plane.

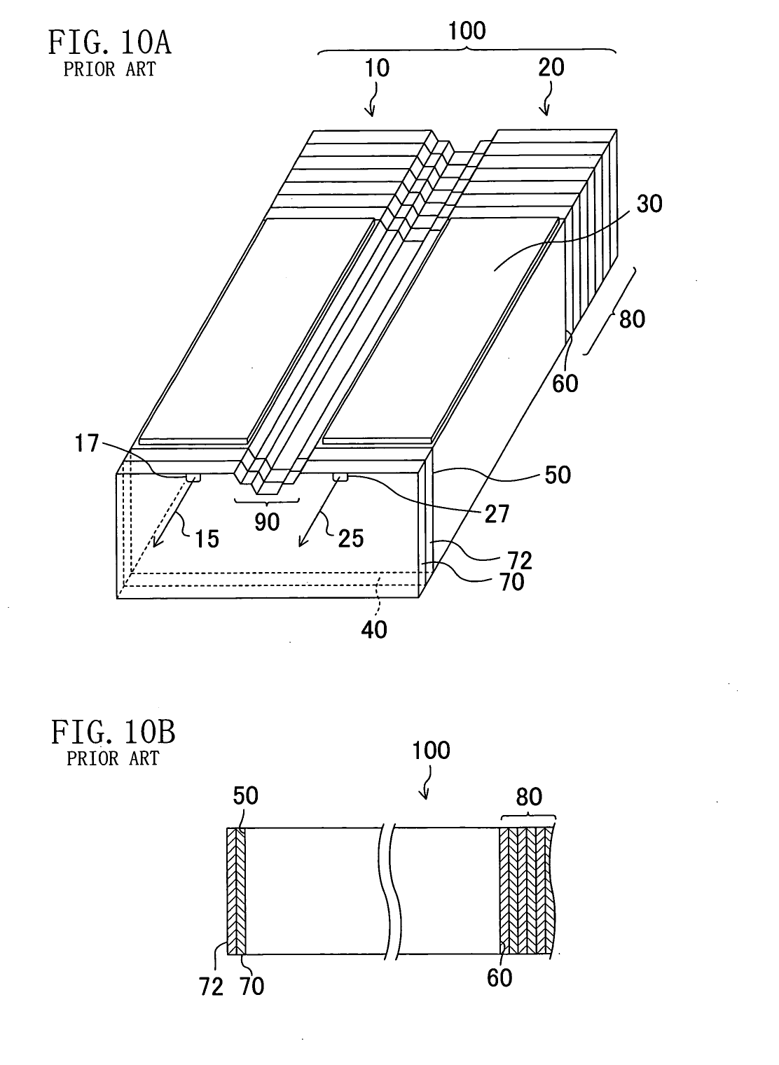

### DETAILED DESCRIPTION OF THE PREFERRED EMBODIMENTS

One embodiment of the present invention will be described in detail with reference to accompanying drawings.

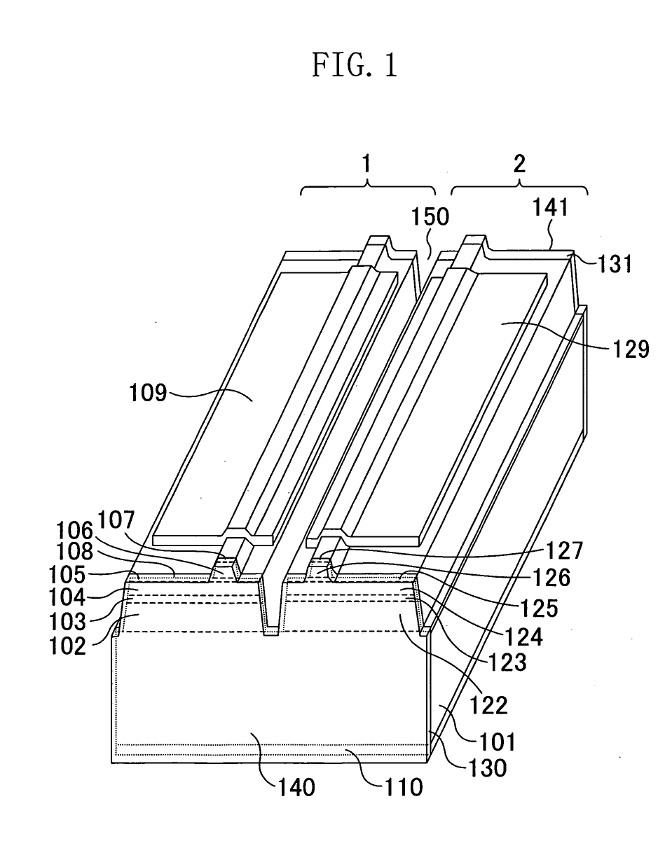

FIG. 1 shows the schematic structure of a dual-wavelength semiconductor laser device according to one embodiment of the present invention. As shown in FIG. 1, in the dual-wavelength semiconductor laser device according to the present embodiment, a red semiconductor laser element 1 for generating a laser light having a band at 660 nm and an infrared semiconductor laser element 2 for generating a laser light having a band at 780 nm are formed on a substrate 101 monolithically.

The red semiconductor laser element 1 is so structured that a first n-type cladding layer 102, a first active layer 103, a first p-type cladding layer 104, a first etch stop layer 105, a second p-type cladding layer 106, a first p-type contact layer 107, and an insulating layer 108 are formed sequentially in this order on the substrate 101 for epitaxial growth.

The infrared semiconductor laser element 2 is different in composition from and has the same structure as the red semiconductor laser element 1, namely, an n-type cladding layer 122, a second active layer 123, a third p-type cladding layer 124, an etch stop layer 125, a fourth p-type cladding layer 126, a second p-type contact layer 127, and the insulating layer 108 are formed on the substrate 101 sequentially in this order.

The red semiconductor laser element 1 and the infrared semiconductor laser element 2 are isolated electrically by an isolation trench 150 of which bottom reaches the substrate 101.

The insulating layer 108 covers, except the upper faces of a first ridge stripe portion and a second ridge stripe portion, the upper face of each etch stop layer 105, 125 and the side face of each ridge stripe portion, wherein the first ridge stripe portion is in a protruding trapezoidal structure in section formed of the second p-type cladding layer 106 in the red semiconductor laser element 1 and the second ridge stripe portion is in a protruding trapezoidal structure in section formed of the fourth p-type cladding layer 126 in the infrared semiconductor laser element 2.

On the upper face of the first ridge stripe portion of the red semiconductor laser element 1, a first p-side electrode 109 is formed, from which carriers (holes) are introduced to the first active layer 103 through the first ridge stripe portion. Similarly, a second p-side electrode 129 is formed on the upper face of the second ridge stripe portion of the infrared semiconductor laser element 2, from which carriers (holes) are introduced to the second active layer 123 through the second ridge strip portion.

An n-side electrode 110 is formed on the face of the substrate 101 on the other side of the p-side electrodes 109, 129. With this structure, individual application of bias voltage to the p-side electrodes 109, 129 and the n-side electrode 110 attains independent operation of the semiconductor laser elements 1, 2.

Respective two opposite facets of cavities formed below the ridge stripe portions are coated with a first facet coating film 130 and a second coating film 131, which are made of dielectrics. The first facet coating film 130 forms a light emitting facets (front facets) 140 at facets from which laser lights are emitted while the second facet coating film 131 forms reflection facets (rear facets) 141 at facets which are located opposite the light emitting facets 140 and on which the laser lights are reflected.

Wherein, the facet coating films 130, 131 are made of a plurality of dielectric films which are different in refractive indices from each other, and adjustment of the refractive indices, the film thickness, or the number of layers of the dielectric films can attain a desired reflectance.

It is noted that each ridge stripe portion is not limited to the trapezoidal form in section and may be in a rectangular shape in section of which side face is substantially perpendicular to the plane of the substrate 101.

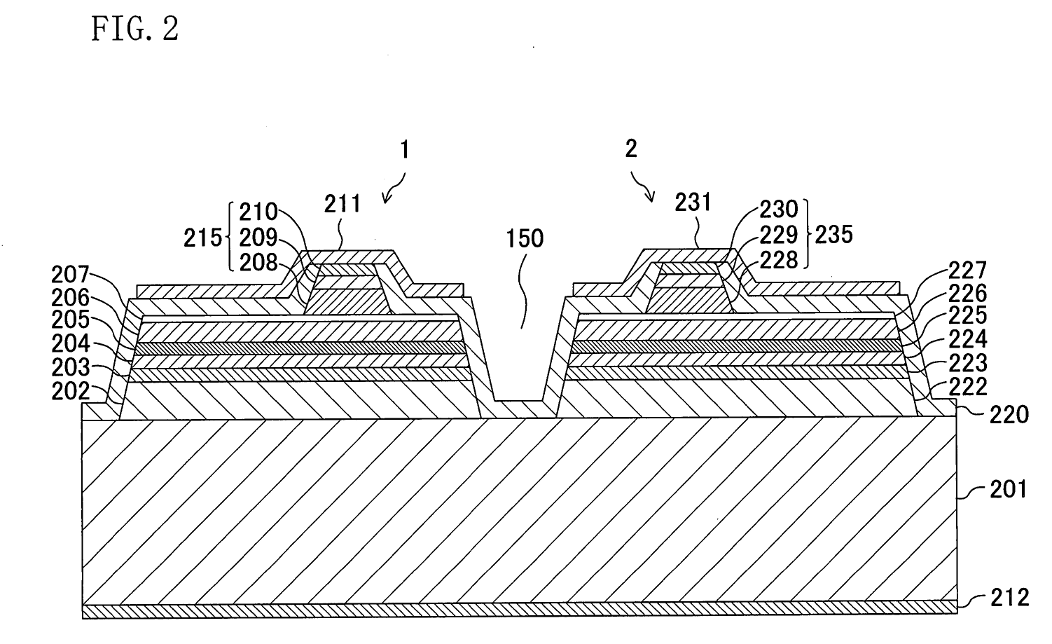

On example of the specific structure and composition of the semiconductor laser device will be described below with reference to FIG. 2.

FIG. 2 shows the sectional construction in the direction perpendicular to the direction in which each ridge stripe portion extends in the semiconductor laser device according to the present embodiment. As shown in FIG. 2, in the red semiconductor laser element 1, there are formed in this order by epitaxial growth on a substrate 201 made of n-type GaAs and having a thickness of 100 μm, a first n-type cladding layer 202 made of n-type (Al_{0.7}Ga_{0.3})_{0.5}In_{0.5}P having a thickness of 2 μm, a first waveguide layer 203 made of (Al_{0.5}Ga_{0.5})_{0.5}In_{0.5}P having a thickness of 0.01 μm, a first multi-quantum well (MQW) active layer 204 in a multi-quantum well structure including AlGaInP/GaInP, a second waveguide layer 205 made of (Al_{0.5}Ga_{0.5})_{0.5}In_{0.5}P having a thickness of 0.01 μm, a first p-type cladding layer 206 made of p-type (Al_{0.7}Ga_{0.3})_{0.5}In_{0.5}P having a thickness of 0.3 μm, a first etch stop layer 207 made of p-type Ga_{0.5}In_{0.5}P having a thickness of 0.007 μm, a second p-type cladding layer 208 made of p-type (Al_{0.7}Ga_{0.3})_{0.5}In_{0.5}P having a thickness of 1.0 μm, a p-type Ga_{0.5}In_{0.5}P layer 209 having a thickness of 0.05 μm, and a first p-type contact layer 210 made of p-type GaAs having a thickness of 0.1 μm.

The first MQW active layer 204 is formed of three paired layers of a well layer made of GaInP having a thickness of 6 nm and a barrier layer made of AlGaInP having a thickness of 7 nm.

The second p-type cladding layer 208, the p-type Ga_{0.5}In_{0.5}P layer 209, and the first p-type contact layer 210 form a first ridge stripe portion 215 in a trapezoidal form in section in the direction perpendicular to the longitudinal direction.

An insulating layer 220, which is made of silicon oxide (SiO₂) having a thickness of 1.0 μm, covers the upper face of the first etch stop layer 207, the side face of the first ridge stripe portion 215, and the bottom face and the side face of the isolation trench 150.

On the insulating layer 220 and the upper face of the first ridge stripe portion 215, a first p-side electrode 211 made of a layered film of titanium (Ti)/Platinum (Pt)/gold (Au) formed from the first p-type contact layer 210 side in this order is formed, wherein the first p-side electrode 211 has a thickness of 1 μm and has an ohmic characteristic. Carriers (holes) are introduced from the first p-side electrode 211 to the first MQW active layer 204 through the first ridge stripe portion 215.

On the face (reverse face) of the substrate 201 on the other side of the first n-type cladding layer 202, an n-side electrode 212 made of a layered film of gold germanium (AuGe)/nickel (Ni)/gold (Au)/titanium (Ti)/gold (Au) formed from the substrate 201 side in this order is formed, wherein the n-side electrode 212 has a thickness of 0.5 μm.

On the other hand, in the infrared semiconductor laser element 2, there are formed in this order by epitaxial growth on the substrate 201 made of n-type GaAs and having a thickness of in this order 100 μm, a second n-type cladding layer 222 made of n-type (Al_{0.5}Ga_{0.5})_{0.5}In_{0.5}P having a thickness of 2 μm, a third waveguide layer 223 made of AlGaAs having a thickness of 0.01 μm, a second multi-quantum well (MQW) active layer 224 in a multi-quantum well structure including AlGaAs, a fourth waveguide layer 225 made of AlGaAs having a thickness of 0.01 μm, a third p-type cladding layer 226 made of p-type (Al_{0.5}Ga_{0.5})_{0.5}In_{0.5}P having a thickness of 0.3 μm, a second etch stop layer 227 made of p-type Ga_{0.5}In_{0.5}P having a thickness of 0.01 μm, a fourth p-type cladding layer 228 made of (Al_{0.5}Ga_{0.5})_{0.5}In_{0.5}P having a thickness of 1.0 μm, a p-type Ga_{0.5}In_{0.5}P layer 229 having a thickness of 0.05 μm, and a second p-type contact layer 230 made of p-type GaAs having a thickness of 0.1 μm.

The second MQW active layer 224 is formed of two paired layers of a well layer having a thickness of 3 nm and a barrier layer having a thickness of 7 nm.

The fourth p-type cladding layer 228, the p-type Ga_{0.5}In_{0.5}P layer 229, and the second p-type contact layer 230 form a second ridge stripe portion 235 in a trapezoidal form in section in the direction perpendicular to the longitudinal direction.

The insulating layer 220 covers the upper face of the second etch stop layer 227 and the side face of the second ridge stripe portion 235 continuously from the side face of the isolation trench 150.

A second p-side electrode 231, which is formed on the insulating layer 220 and the upper face of the second ridge stripe portion 235, has the same structure as the first p-side electrode 211 so that carriers (holes) are introduced from the second p-side electrode 231 to the second MQW active layer 224 through the second ridge portion 235.

In the semiconductor laser device of the present embodiment, the length of the cavities, and the width and the height of the chip are 1200 μm, 120 μm, and 80 μm, respectively. The width and the height of each ridge strip portion 215, 235 are approximately 2.5 μm and 1.15 μm, respectively.

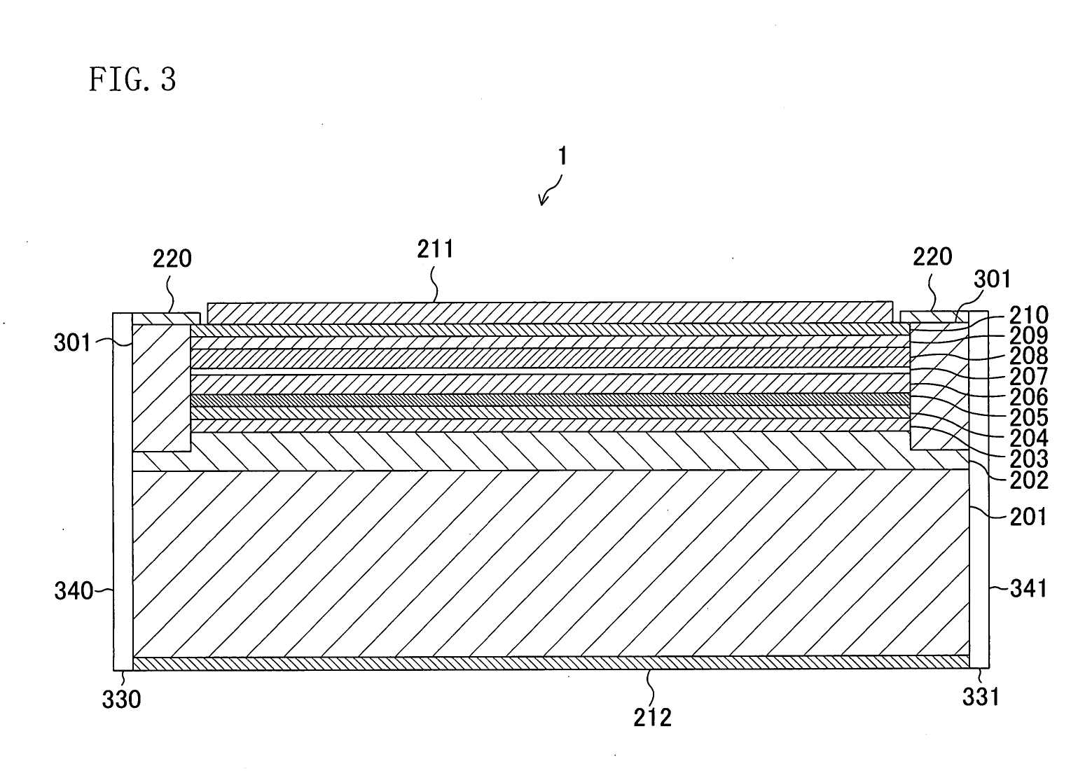

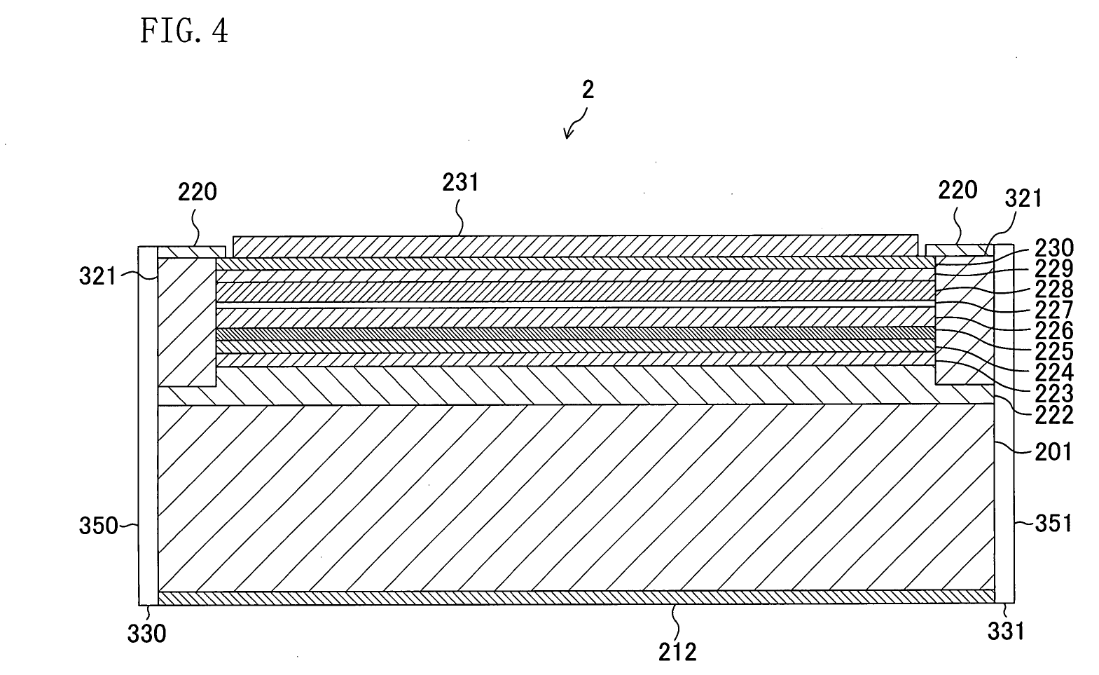

FIG. 3 shows the sectional structure of a region which includes the first ridge stripe portion 215 in the direction (cavity direction) parallel to the cavity of the red semiconductor laser element 1. While, FIG. 4 shows the sectional construction of a region which includes the second ridge stripe portion 235 in the cavity direction in the infrared semiconductor laser element 2. Wherein, in FIG. 3 and FIG. 4, the same reference numerals are assigned to the same elements as those shown in FIG. 2.

As shown in FIG. 3 and FIG. 4, in order to attain high power output operation by preventing facet breakdown by COD, in the semiconductor laser device of the present embodiment, first window regions 301 and second window regions 321, of which width in the cavity direction is 20 μm and to which an impurity is added, are formed at the respective ends of the respective cavities in the laser light resonating direction. Further, each upper portion of the window regions 301, 321 is covered with the insulating layer 220 for preventing introduction of the carriers to the window regions 301, 321.

The front facets of the cavities serve as the light emitting facets 340, 350 for taking out the laser lights while the rear facets of the cavities serve as the reflection facets 341, 351 for allowing the lights to reflect in the inside of the cavities.

In order to adjust the reflectance of the light emitting facets 340, 350, a first facet coating film 330 of two layers of dielectrics of which refractive indices are different from each other is formed at each of the light emitting facets 341, 350. Also, a second facet coating film 331 formed of a plurality of layers of dielectrics is formed at each of the reflection facets 341, 351.

Herein, the second facet coating film 331 formed at the rear facets is in a multi-layered structure of a low-refractive index film and a high-refractive index film for setting the reflectance of the second facet coating film 331 to be 70% or more, preferably, 90% or more. For example, silicon oxide (SiO₂) having a refractive index of 1.48 is used as a low-refractive index material while hydrogenated amorphous silicon of which refractive index in a real part is 3.3 is used as a high-refractive index material.

The first facet coating film 330 forming the front facets is set to have a reflectance in the range between 1% and 7%, both inclusive.

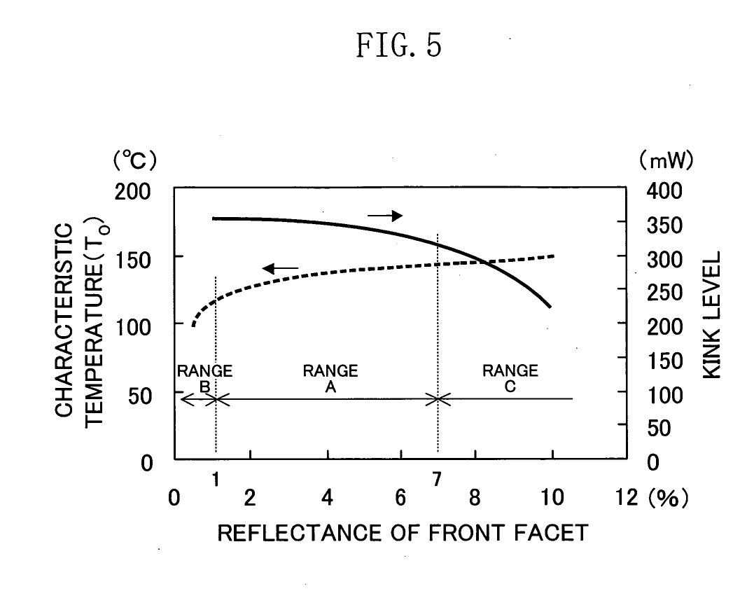

The reason why the reflectance is so set will be described with reference to FIG. 5. FIG. 5 indicates dependencies of characteristic temperature T₀ and kink level on reflectance of the front facet of the red semiconductor laser element 1. As shown in FIG. 5, when the reflectance of the front facet is in the range indicated by B in the drawing, namely, is 1% or less, the characteristic temperature T₀ lowers. This is because mirror loss increases in the range B where the reflectance is low to invite increase in threshold gain, thereby increasing a threshold current. This tendency is remarkable in a high temperature region where the differential gain lowers, so that the operation current largely increases at high temperatures (70° C. or higher, for example).

On the other hand, when the reflectance of the front facet is in the range indicated by C in the drawing, namely, is 7% or more, the kink level lowers. This is due to decrease in external differential quantum efficiency (slope efficiency: ratio between variation in light output and variation in current). FIG. 5 shows the case of the red semiconductor laser element 1, wherein the same tendency is exhibited in the infrared semiconductor laser element 2. Accordingly, it is much desirable to set the reflectance of the front facets (light emitting facets) of the cavities to be in a range between 1% and 7%, both inclusive, as shown by the range A in the drawing.

For setting the reflectance of the front facets to be in the range between 1% and 7%, both inclusive, in the semiconductor laser device of the present embodiment, a first dielectric film having a refractive index of n₁ and a film thickness of t₁ and a second dielectric film having a refractive index of n₂ and a film thickness of t₂ on the first dielectric film are formed as the first facet coating film 330 at the light emitting facets 340, 350 from which the laser lights are emitted, where the oscillation wavelengths of the red semiconductor laser element 1 and the infrared semiconductor laser element 2 are λ₁ and λ₂, respectively. Herein, the film thickness t₁ of the first dielectric film is set to be λ/(8n₁) and the film thickness t₂ of the second dielectric film is set to be λ/(8n₂). Wherein, λ is a wavelength between λ₁ and λ₂. More preferably, λ is an intermediate wavelength between λ₁ and λ₂.

Further, in the semiconductor laser device of the present embodiment, the refractive index n₁ of the first dielectric film is set in the range 1.6≦n₁≦2.3 while the refractive index n₂ of the second dielectric film is set in the range 1.4≦n₂<1.6.

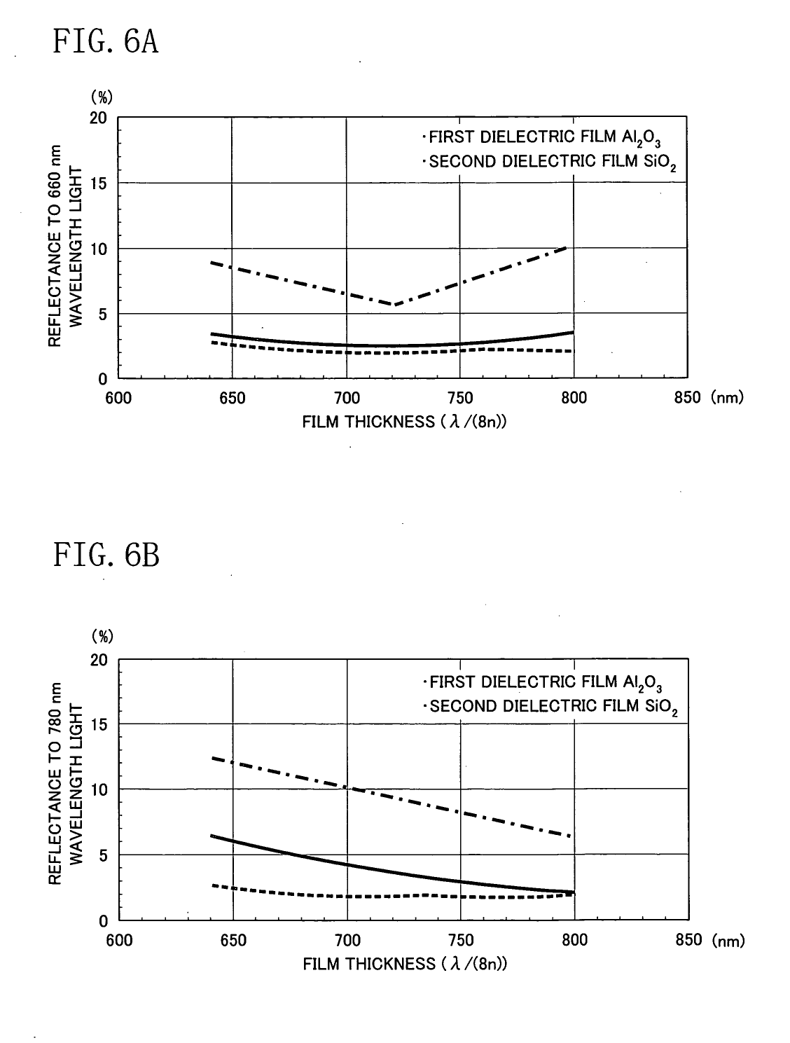

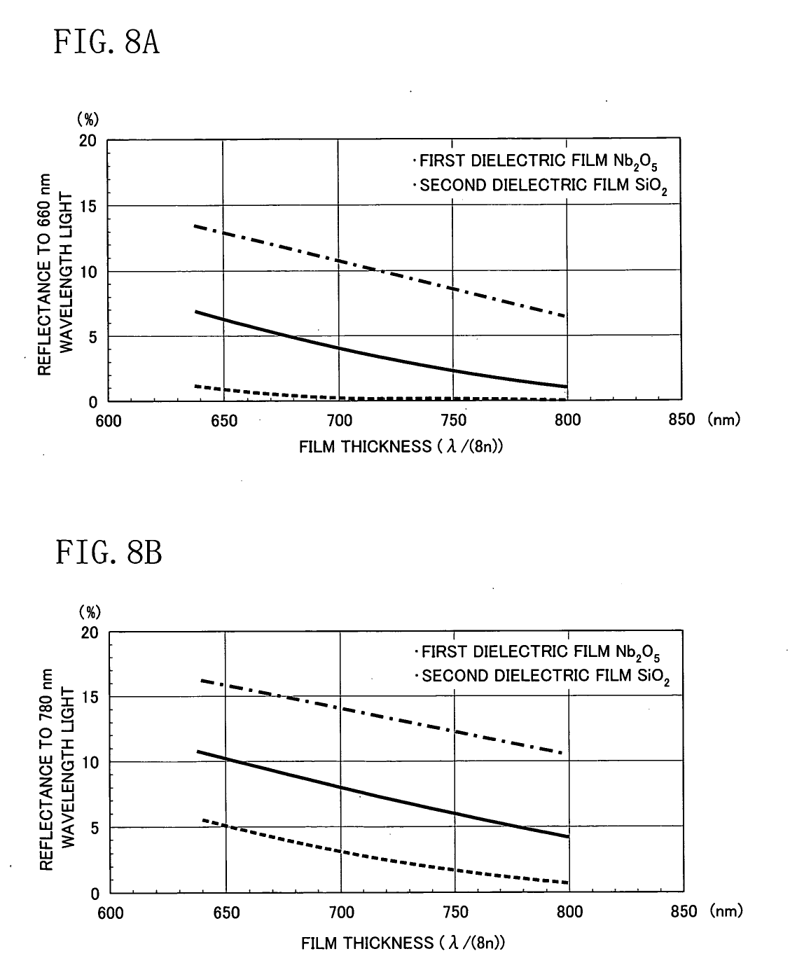

FIG. 6A and FIG. 6B through to FIG. 8A and FIG. 8B show the relationship between the total film thickness of the below-mentioned dielectric films forming the first facet coating film 330 and the reflectance of the front facets. Herein, the film thickness of each dielectric film is given as λ/(8n) which is a value obtained by dividing the wavelength λ by 8n and the axis of abscissas indicates the film thickness as the wavelength. The solid lines indicate the facet reflectance where the film thickness of each dielectric film is λ/(8n), and the broken lines and the dash-dot line indicate the minimum facet reflectance and the maximum facet reflectance, respectively, where the film thickness of each dielectric film is changed ±20% from λ/(8n). Also, the film thicknesses of the dielectric films are given as λ/(8n₁) and λ/(8n₂) with respect to the wavelength λ on the axis of abscissas, wherein n₁ and n₂ are the refractive indices of the dielectric films with respect to the wavelength λ.

Specifically, FIG. 6A and FIG. 6B indicate the reflectances with respect to the lights having wavelengths of 660 nm or 780 nm, respectively, where aluminum oxide (Al₂O₃) is used for the first dielectric film in contact with the cavities and silicon oxide (SiO₂) is used for the second dielectric film formed on the first dielectric film. In the dielectric films, the refractive indices of Al₂O₃ and SiO₂ are 1.652 and 1.492, respectively, with respect to the light having a wavelength of 660 nm, and the refractive indices of Al₂O₃ and SiO₂ are 1.647 and 1.491, respectively, with respect to the light having a wavelength of 780 mm.

In the present embodiment, the effective refractive index that the red semiconductor laser element 1 of which oscillation wavelength is 660 nm has is 3.357 while the effective refractive index that the infrared semiconductor laser element 2 of which oscillation wavelength is 780 nm has is 3.236.

As can be understood from FIG. 6A and FIG. 6B, the result of calculation of 640 nm to 800 nm designed wavelengths to the film thickness of the first coating film 330 shows that the reflectance with respect to the respective lights having a wavelength of 660 nm or 780 nm can be adjusted to be in the range between 2% and 7%, both inclusive. The reflectance of the first facet coating film 330 can be adjusted by deviating the film thickness of each dielectric film from λ/(8n) or by adjusting the designed wavelength λ to the film thickness. Accordingly, the reflectance within the range between 2% and 7%, both inclusive, which is the target range, can be attained with respect to two kinds of lights having wavelengths of 660 nm or 780 nm.

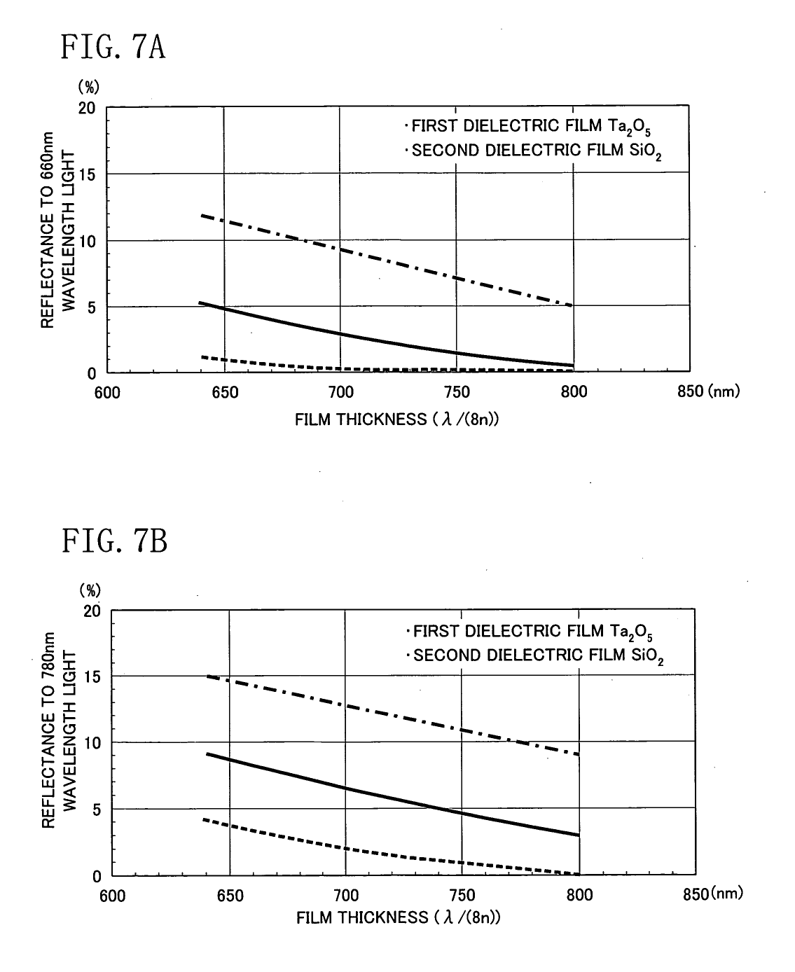

Referring next to FIG. 7A and FIG. 7B, they indicate the reflectances with respect to the lights having wavelengths of 660 nm or 780=n, respectively, where tantalum oxide (Ta₂O₅) is used for the first dielectric film and silicon oxide (SiO₂) is used for the second dielectric film. The refractive index of Ta₂O₅ forming the first dielectric film is 2.078 with respect to the light having a wavelength of 660 nm and 2.057 with respect to the light having a wavelength of 780 nm. As such, the refractive index of Ta₂O₅ is greater than that of the Al₂O₂, and therefore, a region where the reflectance with respect to the light having a wavelength of 660 mm is 1% or less appears even with the film thickness of each dielectric films set to be λ/(8n). In this connection, a reflectance variation range where the film thickness is deviated ±20% from λ/(8n) becomes larger than that where Al₂O₃ is used for the first dielectric film, which requires further precise film thickness setting for adjusting the reflectance of the first facet coating film 330 to be in the range between 1% and 7%, both inclusive.

Further, FIG. 8A and FIG. 8B indicate the reflectances with respect to the lights having wavelengths of 660 nm or 780 nm, respectively, where niobium oxide (Nb₂O₅) is used for the first dielectric film and silicon oxide (SiO₂) is used for the second dielectric film. In this case, also, the refractive index of Nb₂O₅ forming the first dielectric film is high, namely, 2.235 with respect to the light having a wavelength of 660 nm and 2.207 with respect to the light having a wavelength of 780 nm, so that a region where the reflectance is 1% or less appears, as well as in the case of Ta₂O₅ shown in FIG. 7. Hence, further precise film thickness setting is required for adjusting the reflectance of the first facet coating film 330 to be in the range between 1% and 7%, both inclusive.

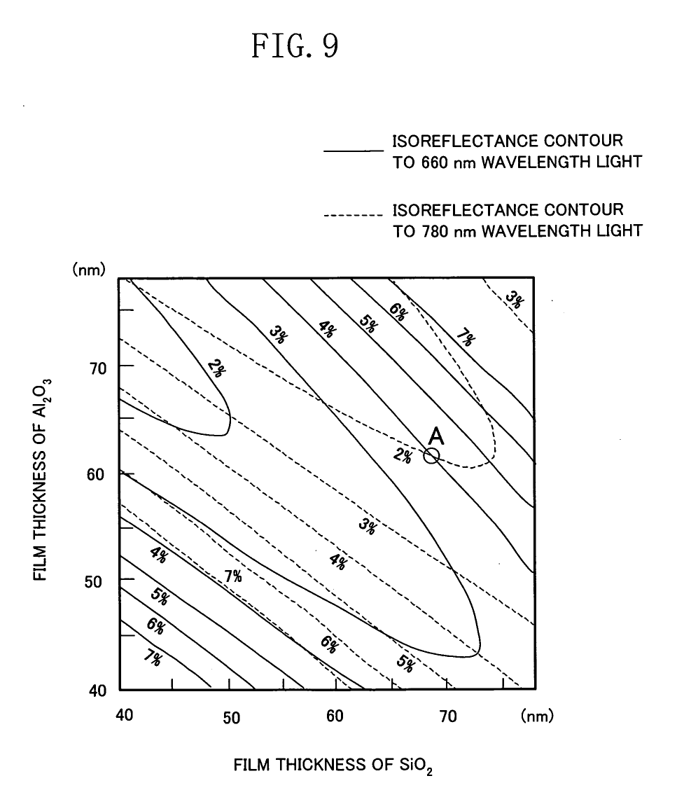

FIG. 9 shows calculation result regarding the film thickness of the first facet coating film 330 for obtaining the target reflectance to the light having a wavelength of 660 nm and the light having a wavelength of 780 nm in the case where Al₂O₃ is used for the first dielectric film and SiO₂ is used for the second dielectric film. Herein, the axis of ordinates indicates the film thickness of Al₂O₃ forming the first dielectric film while the axis of abscissa indicates the film thickness of SiO₂ forming the second dielectric film. Also, the solid lines indicate isoreflectance contour to the light having a wavelength of 660 nm and the broken lines indicate isoreflectance contours to the light having a wavelength of 780 nm.

As shown in FIG. 9, each intersection point of the solid lines and the broken lines indicates reflectance (1% intervals) to the light having a wavelength of 660 nm and the light having a wavelength of 780 nm, which can be realized by the combination of Al₂O₃ and SiO₂ having corresponding film thicknesses. For example, the intersection point in the circle A marked in FIG. 9 shows that the film thicknesses of Al₂O₃ and SiO₂ are set to 62 nm and 68 nm, respectively, for attaining 4% reflectance to the light having a wavelength of 660 nm and 2% reflectance to the light having a wavelength of 780 nm.

Further, FIG. 9 proves that with no intersection point within the range shown in FIG. 9, a reflectance combination that cannot be realized is present, such as a combination of 4% reflectance to the light having a wavelength of 660 nm and 4% reflectance to the light having a wavelength of 780 nm, for example.

In the present embodiment, it is understood from this calculation example that change in film thicknesses of the first dielectric film and the second dielectric film within a predetermined range (approximately ±20%) from λ/(8n) attains setting of the reflectance on both the light having a wavelength of 660 nm and the light having a wavelength of 780 nm to be in a predetermined range.

It is noted that it is preferable to use aluminum oxide (Al₂O₃) and silicon oxide (SiO₂) for the first dielectric film in contact with the cavities and the second dielectric film on the first dielectric film, respectively. The reason for the preference will be described below.

Dielectric films made of oxides such as Al₂O₃, SiO₂, Ta₂O₅, or Nb₂O₅ have less stress in general, though it depends on a deposition method, and accordingly, are suitable for the facet coating films 330, 331 of the semiconductor laser elements. In view of the stress, it is preferable to make the film thickness of the facet coating films 330, 331 thinner.

Further, when the dielectric film made of Al₂O₃, Ta₂O₅, or Nb₂O₅, which have thermal conductivities higher than SiO₂, is formed so as to be in contact with the facets of the cavities, namely, is formed as the first dielectric film, the heat release characteristic of the facets becomes excellent. As a result, reliability in high power output operation increases. While the film thickness is preferably thick in view of the heat release characteristic, the present inventors have found that setting of the film thickness of the first facet coating film 330 to be λ/(8n) or a value therearound is preferable in view of both the stress and the heat release characteristic.

The dielectric film made of oxide can be deposited by electron cyclotron resonance (ECR) sputtering, magnetron sputtering, or electron beam (EB) evaporation. Especially, ECR sputtering can use a metal (Si, Al, Ta, or Nb, for example) having a high impurity as a target material and can form a dielectric film that absorbs no light at a high deposition rate, which means preferable. For example, when metal aluminum (Al) is used as a target material and oxygen (O₂) is used as a reactive gas, Al₂O₃ can be formed at a high deposition rate of 20 nm/min, leading to excellent productivity.

Furthermore, the present inventors have also found an additional effect obtained by using Al₂O₃, Ta₂O₅, or Nb₂O₅ at the facets of the cavities as the first dielectric film rather than SiO₂. In detail, they have found that: when SiO₂ is deposited by the aforementioned sputtering method, metal elements such as Fe, Cr, and the like, which are impurities in a reaction furnace, become liable to be taken into the dielectric film; and when laser operation at high output power is performed in the state where the thus formed dielectric film (SiO₂ film) containing the heavy metal is in direct contact with the facets of the cavities, the contaminant metal taken in the SiO₂ film degrades the cavity facets.

This facet degradation may be due to local heat generation by light absorption by the impurities in the dielectric film. It has been already found that an Al₂O₃ film formed by sputtering causes no facet degradation with low contamination level of the impurities compared with the case of the SiO₂ film, and hence, it is understood that the Al₂O₃ film is remarkably effective in preventing facet degradation in high power output operation.

Moreover, the Al₂O₃ film is excellent in adhesiveness to semiconductor made of GaAs and exhibits an excellent characteristic against harsh environment, and therefore, it can be mounted to a package in which a laser chip is not sealed in an airtight manner, increasing the reliability.

It is noted that the use of Al₂O₃ for the first dielectric film is also effective in the second facet coating film 331 forming the rear facets of the cavities. In order to increase the reflectance as far as possible, one dielectric film having a thickness of λ/(4n) and a low refractive index and another dielectric film having a refractive index higher than the one dielectric film are deposited alternately on the rear facet. When the number of pairs of the one dielectric film and the other dielectric film is increased, the reflectance increases.

The greater the difference in refractive index between the paired dielectric films is, the higher the reflectance is. For example, SiO₂ may be used for the one dielectric film having a small refractive index while hydrogenated amorphous Si may be used for the other dielectric film having a high refractive index. Amorphous Si absorbs laser light, and therefore, another dielectric may be used. For example, Ta₂O₅, Nb₂O₅, ZrO₂, or TiO₂, which are smaller in refractive index than amorphous Si through, may be used.

In a case using SiO₂ as the dielectric film having a small refractive index, formation of SiO₂ so as to be in direct contact with the cavity facets may cause facet degradation, as described above. Therefore, a SiO₂ film having a thickness of approximately λ/(8n) is formed on an Al₂O₃ film formed so as to have a thickness of approximately λ/(8n) and a hydrogenated amorphous Si film having a thickness of λ/(4n) is formed on the thus formed SiO₂ film, so that the thus formed films serve as the second facet coating film 331 having high reliability.

In order to further increase the reflectance of the second facet coating film 331, one or more pairs of an SiO₂ film and a hydrogenated amorphous Si film both of which have a thickness of λ/(4n) may be formed on the previously formed hydrogenated amorphous Si film in this order.

As described above, in the dual-wavelength semiconductor laser device according to the present embodiment, when the first dielectric film and the second dielectric film having the predetermined refractive indices, namely, a refractive index of n₁ in the range 1.6≦n₁≦2.3 and a refractive index n₂ in the range 1.4≦n₂<1.6, respectively, are formed so as to have predetermined film thicknesses, they can serve as the first facet coating film 330 suitable for high power output operation while a high reflectance and light emitting facets having high reliability can be attained easily. Herein, the predetermine film thicknesses are approximately λ/(8n₁) for the first dielectric film and approximately λ/(8n₂) for the second dielectric film. Further, λ is a wavelength between the oscillation wavelength λ₁ of the red semiconductor laser device 1 and the oscillation wavelength λ₂ of the infrared semiconductor laser device.

In addition, in the semiconductor laser device of the present embodiment, a first facet coating film 330 having the reflectance suitable for high power output operation can be obtained easily, raising the kink level to lead to increase in reliability in high power output operation and increase in production yield.

It is noted that the present embodiment refers to the dual-wavelength semiconductor laser device but the present invention is not limited thereto. The present embodiment is applicable to a single-wavelength semiconductor laser device in which only one of the red semiconductor laser element 1 and the infrared semiconductor laser element 2 is formed on the substrate 201. This application realizes a high power output single-wavelength semiconductor laser device with reliability to the same degree as that of the above dual-wavelength semiconductor laser device.

As described so far, in the semiconductor laser device of the present invention, multilayered film of dielectrics having a reflectance suitable for high power output operation can be formed at the light emitting facets easily, raising the kink level to lead to increase in reliability in high power output operation and increases in yield of the dual-wavelength semiconductor laser device. Accordingly, the present invention is useful to light sources for optical recording devices needing a high power output dual-wavelength semiconductor laser device and is also useful in application to laser medical care, and the like.

What is claimed is:

1. A semiconductor laser device, comprising:
a first semiconductor laser element formed on one substrate for emitting a first laser light having a first oscillation wavelength of λ₁; and
a second semiconductor laser element formed on the substrate for emitting a second laser light having a second oscillation wavelength of λ₂ (wherein λ₂≧λ₁),
wherein a first dielectric film which has a refractive index of n₁ with respect to a wavelength λ between the first oscillation wavelength λ₁ and the second oscillation wavelength λ₂ and has a film thickness of approximately λ/(8n₁) is formed at light emitting facets in the first semiconductor laser element and the second semiconductor laser element, from which the laser lights are emitted, and
a second dielectric film which has a refractive index of n₂ and has a film thickness of approximately λ/(8n₂) is formed on the first dielectric film.

2. The semiconductor laser device of claim 1,
wherein the first oscillation wavelength λ₁ and the second oscillation wavelength λ₂ are equal to the wavelength λ.

3. The semiconductor laser device of claim 1,
wherein a reflectance of the light emitting facets is in a range beaten 1% and 7%, both inclusive.

4. The semiconductor laser device of claim 1,
wherein the refractive index n₁ is in a range 1.6≦n₁≦2.3 and the refractive index n₂ is in a range 1.4≦n₂<1.6.

5. The semiconductor laser device of claim 1,
wherein the first dielectric film is made of Al₂O₃, Ta₂O₅, Nb₂O₅, or ZrO₂ while the second dielectric film is made of SiO₂.

6. The semiconductor laser device of claim 1,
wherein the first semiconductor laser element has an active layer made of AlGaInP-based semiconductor while the second semiconductor laser element has an active layer made of AlGaAs-based semiconductor.

7. A semiconductor laser device, comprising:
a first semiconductor laser element formed on one substrate for emitting a first laser light having a first oscillation wavelength of λ₁; and
a second semiconductor laser element formed on the substrate for emitting a second laser light having a second oscillation wavelength of λ₂ (wherein λ₂≧λ₁),
wherein a first dielectric film which has a refractive index of n₁ with respect to a wavelength λ between the first oscillation wavelength λ₁ and the second oscillation wavelength λ₂ and has a film thickness of approximately λ/(8n₁) is formed at reflection facets located opposite light emitting facets in the first semiconductor laser element and the second semiconductor laser element, from which the laser lights are emitted,
a second dielectric film which has a refractive index of n₂ and has a film thickness of approximately λ/(8n₂) is formed on the first dielectric film,
a third dielectric film having a refractive index of n₃ (wherein n₃>n₁ and n₂) and has a film thickness of approximately λ/(4n₃) is formed on the second dielectric film, and
a plurality of pairs of dielectric films are formed on the third dielectric film, each of the paired dielectric films being composed of a fourth dielectric film having a refractive index of n₄ and a film thickness of λ/(4n₄) and a fifth dielectric film having a refractive index of n₅ and a film thickness of λ/(4n₅).

8. The semiconductor laser device of claim 7,
wherein the first oscillation wavelength λ₁ and the second oscillation wavelength λ₂ are equal to the wavelength λ.

9. The semiconductor laser device of claim 7,
wherein a reflectance of the reflection facets is 70% or more.

10. The semiconductor laser device of claim 7,
wherein the refractive index n₁ is in a range 1.6≦n₁≦2.3 and the refractive index n₂ is in a range 1.4≦n₂<1.6.

11. The semiconductor laser device of claim 7,
wherein the first dielectric film is made of Al₂O₃, Ta₂O₅, Nb₂O₅, or ZrO₂ while the second dielectric film is made of SiO₂.

12. The semiconductor laser device of claim 7,
wherein the first semiconductor laser element has an active layer made of AlGaInP-based semiconductor while the second semiconductor laser element has an active layer made of AlGaAs-based semiconductor.
